(19) United States
(12) Patent Application Publication
(10) Pub. No.: US 2013/0062642 A1
(43) Pub. Date: Mar. 14, 2013

(54) LED PACKAGE DEVICE

(71) Applicants: PI-CHIANG HU, Hukou (TW); MENG-HSIEN HONG, Hukou (TW); SHIH-YUAN HSU, Hukou (TW)

(72) Inventors: PI-CHIANG HU, Hukou (TW); MENG-HSIEN HONG, Hukou (TW); SHIH-YUAN HSU, Hukou (TW)

(73) Assignee: ADVANCED OPTOELECTRONIC TECHNOLOGY, INC., Hsinchu Hsien (TW)

(21) Appl. No.: 13/366,375

(22) Filed: Feb. 6, 2012

(30) Foreign Application Priority Data
Sep. 14, 2011 (CN) 201110271218.7

(51) Int. Cl. H01L 33/60

(52) U.S. Cl. 257/98; 257/E33.061

(57) ABSTRACT

An LED package device comprises a substrate, a first electrode, a second electrode, a reflector, an encapsulation layer and an LED die. The substrate includes a top surface and a bottom surface opposite to the top surface, wherein the first and the second electrodes are located on the top surface of the substrate. A sum of the areas of the first and the second electrodes on the top surface is smaller than ¼-⅔ the area of the top surface. Therefore, an increased contacting area between the reflector and the substrate is formed to enhance the tightness of the LED package device.

### 1. TECHNICAL FIELD

The disclosure relates generally to light emitting diode, and particularly to a light emitting diode package device having an enhanced tightness.

### 2. DESCRIPTION OF THE RELATED ART

Light emitting diodes (LEDs) have low power consumption, high efficiency, quick reaction time, long lifetime, and the absence of toxic elements such as mercury during manufacturing. Generally, a reflector is used inside an LED package device to increase the light intensity and render the desired color(s), wherein the reflector may be formed by plastic or polymer such as polyphthalamide (PPA) or other thermoplastic materials. However, a low degree of tightness of the combination between the plastic reflector and a metal electrode located on a substrate of the LED package device may reduce a life of the LED package device. To prevent this, a plurality of through holes may be formed in the metal electrode to increase a contacting area between the reflector and the substrate. However, forming the through holes in the metal electrodes may result in higher cost and increased time to manufacture the LED package devices. Hence, a new design to an LED package device having an enhanced tightness is required.

### BRIEF DESCRIPTION OF THE DRAWINGS

FIG. 1 is a cross-section of an LED package device of the disclosure.

FIG. 2 is a top view of a first electrode and a second electrode on a substrate of the LED package device of FIG. 1.

### DETAILED DESCRIPTION

Exemplary embodiments of the disclosure will be described with reference to the accompanying drawings.

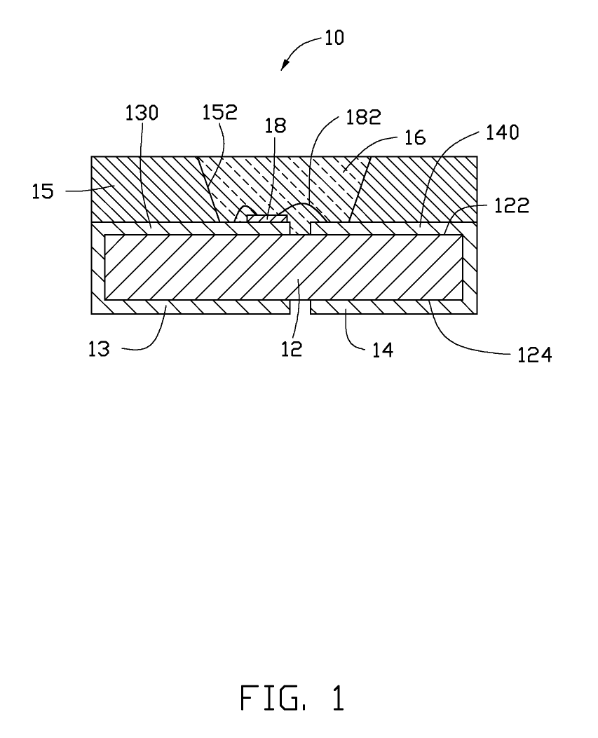

Referring to FIG. 1, the disclosure provides an LED package device 10 comprising a substrate 12, a first electrode 13, a second electrode 14, a reflector 15, an encapsulation layer 16 and an LED die 18. The substrate 12 comprises a top surface 122 and a bottom surface 124 opposite to the top surface 122. The substrate 12 can be made of ceramic, silicon or plastic.

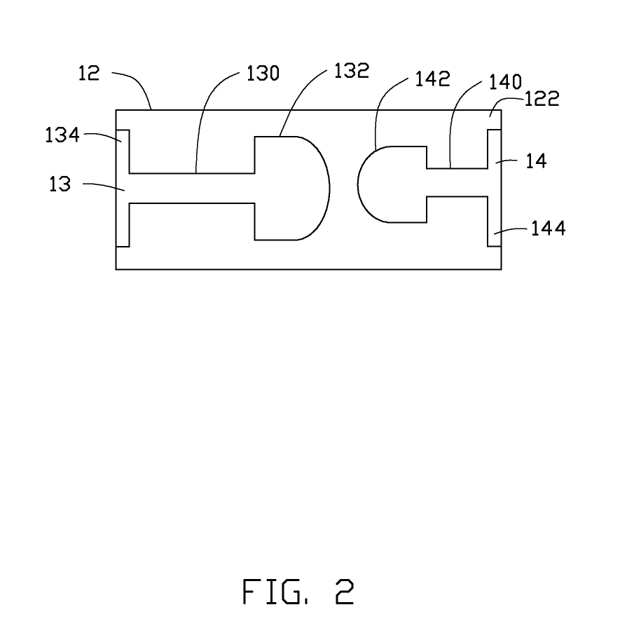

The first electrode 13 comprises a first connecting portion 130 and a first bonding portion 132 both on the top surface 122 of the substrate 12. Also the second electrode 14 comprises a second connecting portion 140 and a second bonding portion 142 both on the top surface 122 of the substrate 12. In the embodiment, the first electrode 13 and the second electrode 14 are separately disposed on two opposite ends of the top surface 122. Moreover, the first electrode 13 and the second electrode 14 respectively extend from the top surface 122 to the bottom surface 124 of the substrate 12. In the embodiment, one of the first electrode 13 and the second electrode 14 is a cathode and the other is an anode. As shown in FIG. 2, the first connecting portion 130 connects to the first bonding portion 132, such that the first connecting portion 130 and the first bonding portion 132 have an equal electric property (polarity). Similarly, the second connecting portion 140 and the second bonding portion 142 have an equal electric property which is reversed to that of the first connecting portion 130 and the first bonding portion 132. In the embodiment, a sum of the areas of the first and the second electrodes 13, 14 on the top surface 122 is about ¼ to about ⅔ of an area of the top surface 122 of the substrate 12. The first bonding portion 132 and the second bonding portion 142 are neighboring to each other, while the first connecting portion 130 extends from an outer edge of the first bonding portion 132 to a lateral side of the top surface 122 to connect with a main body 134 of the first electrode 13. Likewise, the second connecting portion 140 extends from an outer edge of the second bonding portion 142 to an opposite lateral side of the top surface 122 to connect with a main body 144 of the second electrode 14. Each of the first and second bonding portions 132, 142 has a shape of a rectangular patch with an inner side thereof being arched. The first bonding portion 132 has an area larger than that of the second bonding portion 142. A width of each of the first and second connecting portions 130, 140 is smaller than that of each of the first and second bonding portion 132, 142 and also smaller than that of each of the main bodies 134, 144. Each of the first and second connecting portions 130, 140 has a shape of an elongated rectangular strip.

The reflector 15 which is integrated with the substrate is located on the top surface 122 of the substrate 12 and surrounds the LED die 18. The first connecting portion 132 and the second connecting portion 142 are sandwiched between the reflector 15 and substrate 12. The reflector 15 comprises a depression 152 on middle of the top surface 122 of the substrate 12, wherein the first bonding portion 13 and the second bonding portion 14 are located on a bottom of the depression 152. The reflector 15 is used for collecting light emitted from the LED die 18.

The LED die 18 is disposed on the first bonding portion 132 of the first electrode 13 and electrically connected to the first bonding portion 132 of the first electrode 13 and the second bonding portion 142 of the second electrode 14 via conductive wires 142. Alternatively, it also can be achieved by flip chip bonding or eutectic bonding, wherein the LED die 18 is disposed between the first bonding portion 132 and the second bonding portion 142 (not shown).

The encapsulation layer 16 is located on the top surface 122 of the substrate 12 and covers the LED die 18. In the embodiment, the encapsulation layer is disposed inside the depression 152. The encapsulation layer 16 is transparent so that light emitted from the LED die 18 is able to penetrate through the encapsulation layer 16 out of the LED package device 10. Furthermore, the encapsulation layer 16 can comprise a luminescent conversion element (not shown) for producing mixed light with multiple wavelengths.

Accordingly, the sum of the areas of the first and the second electrodes 13, 14 is much less than the area of the top surface 122. That is, the top surface 122 covered by the first and the second electrodes 13, 14 is smaller than that is uncovered. Thus, an increased contacting area between the reflector 15 and the substrate 12 is formed to enhance the tightness of the LED package device 10. Since the areas of the first and the second electrodes 13, 14 are reduced, the manufacturing cost of the LED package device 10 can also be reduced. Moreover, time to manufacture the LED package devices 10 is not increased because no extra manufacturing process is required.

It is to be understood, however, that even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

1. An LED package device, comprising:
a substrate, including a top surface and a bottom surface opposite to the top surface;
a first electrode located on the top surface of the substrate, the first electrode comprising a first bonding portion and a first connection portion extending from an outer edge of the first bonding portion to a lateral side of the top surface to connect with a first main body of the first electrode, wherein the first connection portion is aligned with the first bonding portion and the first connection portion has a width smaller than that of the first bonding portion;
a second electrode located on the top surface of the substrate, the second electrode comprising a second bonding portion and a second connection portion extending from an outer edge of the second bonding portion to a opposite side of the top surface to connect with a second main body of the second electrode, wherein the second connection portion is aligned with the second bonding portion and the second connection portion has a width smaller than that of the second bonding portion;
a reflector, being integrated with the substrate and comprising a depression located on the top surface, wherein the first and the second electrodes are located on a bottom of the depression;
an LED die, disposed on the first bonding portion and electrically connecting to the first and second bonding portions, wherein the first bonding portion and the first connection portion of the first electrode and the second bonding portion and the second connection portion of the second electrode are arranged in a line; and
an encapsulation layer, located in the depression of the reflector and the top surface and covering the LED die.

2. The LED package device as claimed in claim 1, wherein the substrate is made of ceramic, silicon or polymer.

3. The LED package device as claimed in claim 1, wherein the first and the second electrodes respectively extend from the top surface to the bottom surface.

4. The LED package device as claimed in claim 3, wherein one of the first and second electrodes is a cathode and the other is an anode.

5. The LED package device as claimed in claim 1, wherein the LED die electrically connects to the first and the second electrodes by the means of conductive wires or flip chip.

6. The LED package device as claimed in claim 1, wherein a sum of the areas of the first and the second electrodes on the top surface is ¼ to ⅔ of an area of the top surface of the substrate.

7. The LED Package device as claimed in claim 1, wherein the encapsulation layer is transparent and comprises a luminescent conversion element.

8. The LED package device as claimed in claim 1, wherein the first connecting portion and the first bonding portion have an equal electric property.

9. The LED package device as claimed in claim 8, wherein the second connecting portion and the second bonding portion have an equal electric property.

10. The LED package device as claimed in claim 9, wherein the electric property of the second connecting portion and the second bonding portion is reversed to that of the first connecting portion and the first bonding portion.

11. The LED package device as claimed in claim 1, wherein the first and second connecting portions are sandwiched between the reflector and the substrate.

12. An LED package device, comprising:
a substrate, including a top surface and a bottom surface opposite to the top surface;
a cathode located on the top surface of the substrate, the cathode comprising a first bonding portion and a first connection portion extending from the first bonding portion, wherein the first connection portion is aligned with the first bonding portion and the first connection portion has a width smaller than that of the first bonding portion;
an anode located on the top surface of the substrate, the anode comprising a second bonding portion and a second connection portion extending from the second bonding portion, wherein the second connection portion is aligned with the second bonding portion and the second connection portion has a width smaller than that of the second bonding portion;
a reflector, being integrated with the substrate and comprising a depression located on the top surface, wherein the cathode and the anode are located on a bottom of the depression;
an LED die, disposed on one of the anode and cathode and electrically connecting to the anode and cathode, wherein the first bonding portion and the first connection portion of the cathode and the second bonding portion and the second connection portion of the anode are arranged in a line; and
an encapsulation layer, located in the depression, on the top surface and covering the LED die.

13. The LED package device as claimed in claim 12, wherein the substrate is made of ceramic, silicon or polymer.

14. The LED package device as claimed in claim 12, wherein the cathode and the anode respectively extend from the top surface to the bottom surface.

15. The LED package device as claimed in claim 12, wherein the LED die electrically connects to the cathode and the anode by the means of conductive wires or flip chip.

16. The LED package device as claimed in claim 12, wherein a sum of the areas of the cathode and the anode on the top surface is ¼ to ⅔ of an area of the top surface of the substrate.

17. The LED package device as claimed in claim 12, wherein the encapsulation layer is transparent and comprises a luminescent conversion element.

18. The LED package device as claimed in claim 12, wherein the first and second connecting portions are sandwiched between the substrate and the reflector.

19. The LED package device as claimed in claim 18, wherein the first and second bonding portions each have a shape of a rectangular patch with an inner side thereof being arced, and each of the first and second connecting portions has a shape of an elongated, rectangular strip.

20. The LED package device as claimed in claim 19, wherein the LED is disposed on the first bonding portion of the cathode, and the first bonding portion has an area larger than that of the second bonding portion of the anode.
